(19) United States
(12) Patent Application Publication
(10) Pub. No.: US 2025/0101587 A1
(43) Pub. Date: Mar. 27, 2025

(54) METHOD OF MANUFACTURING DEHYDROGENATION CATALYST USING ATOMIC LAYER DEPOSITION

(71) Applicant: KOREA INSTITUTE OF SCIENCE AND TECHNOLOGY, Seoul (KR)

(72) Inventors: Yong Min KIM, Seoul (KR); Suk Woo NAM, Seoul (KR); Hyuntae SOHN, Seoul (KR); Hyangsoo JEONG, Seoul (KR); Sung Pil YOON, Seoul (KR); Sun-Hee CHOI, Seoul (KR); Yu-Jin LEE, Seoul (KR)

(21) Appl. No.: 18/739,029

(22) Filed: Jun. 10, 2024

(30) Foreign Application Priority Data
Sep. 22, 2023 (KR) 10-2023-0126878

(51) Int. Cl. C23C 16/455; B01J 21/04; B01J 21/06; B01J 23/46; B01J 37/02; B01J 37/16; C23C 16/40; C23C 16/56

(52) U.S. Cl. CPC C23C 16/45555; B01J 21/04; B01J 21/063; B01J 23/462; B01J 37/0228; B01J 37/16; C23C 16/405; C23C 16/56

(57) ABSTRACT

Disclosed herein is a method of manufacturing a dehydrogenation catalyst, the method includes: forming a functional oxide coating layer on a surface of a support with a first atomic layer deposition; and depositing metal particles on the surface of the support on which the functional oxide coating layer is formed, with a second atomic layer deposition.

### CROSS REFERENCE TO RELATED APPLICATION

The present application claims priority to Korean Patent Application No. 10-2023-0126878, filed Sep. 22, 2023, the entire contents of which is incorporated herein for all purposes by this reference.

### BACKGROUND OF THE INVENTION

### Field of the Invention

The present invention relates to a method of manufacturing a dehydrogenation catalyst using atomic layer deposition, and more particularly, to a method of manufacturing a dehydrogenation catalyst in which a functional oxide coating layer is formed by atomic layer deposition on a surface of a support, and then metal particles are deposited by the atomic layer and wet impregnation on a surface of the functional oxide coating layer.

### Description about National Research and Development Support

This study was supported by the technology development programs of Ministry of Science and ICT, Republic of Korea (Projects No. 1711196511) under the Korea Institute of Science and Technology.

### Description of the Related Art

With regards to the technology of converting ammonia to hydrogen, research is being carried out on a catalyst to be used in this technology, and there is a need to develop a suitable dehydrogenation catalyst to eventually use hydrogen from ammonia as a fuel.

In particular, various carriers have been used in an attempt to increase a catalytic activity in a dehydrogenation reaction using ruthenium (Ru) as an active material, but most of the conventionally known catalysts for hydrogen production through dehydrogenation requires a large amount of catalyst and an expensive amount of active metal, leading to a problem of being economically unviable.

Meanwhile, to facilitate the reaction of the catalyst, attempts have been made to change the electronic structure of Ru, for example, by using different support materials to allow nitrogen molecules generated during the reaction to desorb rapidly from the catalyst surface. However, in conditions that require a high-temperature environment such as the dehydrogenation reaction, there is a problem in that too strong interaction of metal particles with the support is induced, which hinders the activation of the catalyst.

### SUMMARY OF THE INVENTION

The present invention is directed to solving the problem of blocking and fusing of active sites of metal particles by controlling a thickness of a functional oxide layer generated on a support using atomic layer deposition.

The present invention is directed to providing a method of manufacturing a dehydrogenation catalyst to achieve the aforementioned technical objects, the method may include: forming a functional oxide coating layer on a surface of a support with a first atomic layer deposition; and depositing metal particles on the surface of the support on which the functional oxide coating layer is formed, with a second atomic layer deposition or wet impregnation.

In addition, the support according to the present invention may be porous bead-type Al₂O₃.

In addition, the metal particle according to the present invention may be one of the particles selected from Ru, Pt, Ni, Co, and Mo particles.

In addition, the functional oxide according to the present invention may be one of the oxides selected from TiO₂, CeO₂, ZrO₂ and Al₂O₃.

In addition, the atomic layer deposition according to the present invention may be performed in five cycles.

In addition, Ru particles according to the present invention may be exposed on a surface and not encapsulated by TiO₂.

In addition, the dehydrogenation catalyst manufactured according to the present invention may be subjected to be reduced in a temperature range of 350 to 550° C.

The method according to the present invention may include: rotating an inner barrel device inside a vacuum reactor during operation of the atomic layer deposition.

In the present invention, the content of the functional oxide deposited on the support and the content of the metal particles deposited on the functional oxide coating layer can be reduced.

Further, in the present invention, the properties of the functional oxide coating layer in a high-temperature reductive atmosphere can be modulated.

Further, the dehydrogenation catalyst manufactured according to the present invention can induce a chemical reaction to be expressed only on the surface of the support, and can use the surface properties of the metal particles, thereby improving the productivity of the dehydrogenation catalyst.

### BRIEF DESCRIPTION OF THE DRAWINGS

FIG. 1 is a schematic view illustrating a method of manufacturing a dehydrogenation catalyst according to an embodiment of the present invention.

FIG. 2 is a graph illustrating a conversion rate of ammonia gas according to the number of deposition cycles of a functional oxide coating layer formed according to an embodiment of the present invention.

FIG. 3 is a graph illustrating change in ammonia conversion with the number of deposition cycles of the functional oxide coating layer formed according to an embodiment of the present invention.

FIG. 4 is a graph illustrating metal dispersion as a function of the number of deposition cycles of the functional oxide coating layer formed according to an embodiment of the present invention.

FIG. 5A and FIG. 5B are STEM images of Ru samples with 5 cycles of the functional oxide coating layer formed according to an embodiment of the present invention and 3 wt. % of the functional oxide coating layer formed by wet impregnation method.

FIG. 6 is a photograph schematically illustrating a rotating device equipped with a inner barrel in operation for atomic layer deposition as used in an embodiment of the present invention.

### DETAILED DESCRIPTION OF THE INVENTION

Hereinafter, a method of manufacturing a transition metal catalyst according to a preferred embodiment of the present invention will be described with reference to the accompanying drawings.

Prior to the description, unless explicitly described to the contrary, the word “comprise” or “include” and variations, such as “comprises”, “comprising”, “includes” or “including”, will be understood to imply the inclusion of stated constituent elements, not the exclusion of any other constituent elements.

In addition, in the various embodiments, the constituent elements having the same constitution will be described using the same reference numerals, typically in an embodiment, and only different constituent elements will be described in other embodiments.

Further, while the embodiments of the present invention have been described with reference to the accompanying drawings, they are described for illustrative purposes only and are not intended to limit the technical spirit of the present invention and the constitution and application thereof.

As described above, the present invention relates to a method of manufacturing a dehydrogenation catalyst that is capable of improving the dehydrogenation efficiency of a hydrogen carrier by forming a functional oxide coating layer and metal particles at an atomic layer level.

Accordingly, in the present invention, a functional oxide coating layer and metal particles can be uniformly controlled on a support, and the surface properties of the metal particles can be secured even under high-temperature reductive environment above 300° C. More specifically, the present disclosure will be described with reference to specific embodiments below.

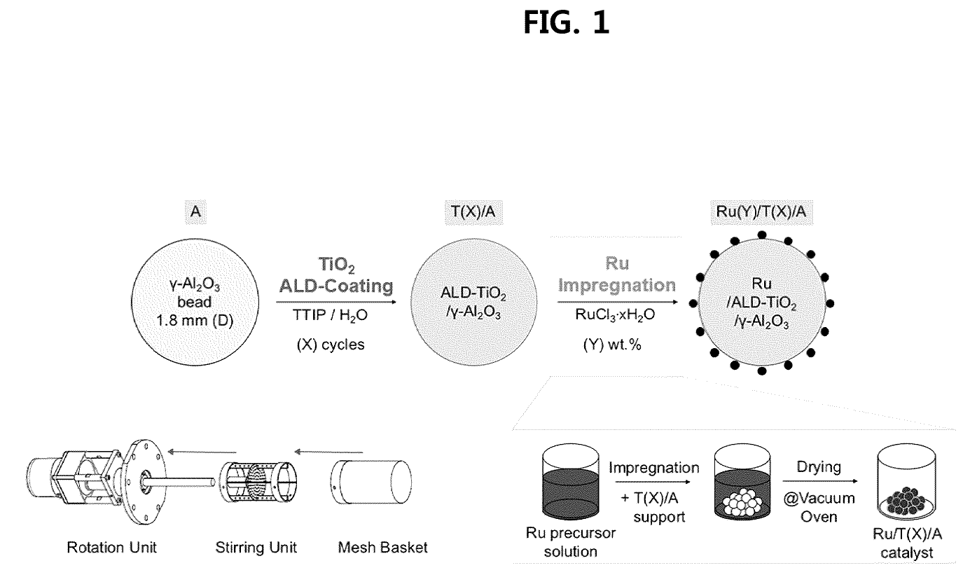

FIG. 1 is a schematic view illustrating a method of manufacturing a dehydrogenation catalyst according to an embodiment of the present invention.

As illustrated in FIG. 1, the method of manufacturing a dehydrogenation catalyst according to the present invention may include: forming a functional oxide coating layer on a surface of a support with a first atomic layer deposition; and depositing metal particles on the surface of the support on which the functional oxide coating layer is formed, with a second atomic layer deposition or wet impregnation.

Therefore, in the present invention, by applying the functional oxide coating layer at an atomic layer level, it is possible to prevent the functional oxide from encapsulating the metal particles, thereby preventing a catalytic activity from being decreased.

In addition, in the present invention, it is possible to improve an ammonia decomposition activity by increasing the density of surface hydroxyl groups that act as interaction sites between the metal particles and the functional oxide coating layer and the dispersion rate of the metal particles through surface modification by introducing the functional oxide coating layer using atomic layer deposition on the support.

Specifically, in an embodiment of the present invention below, a target for dehydrogenation is set to be ammonia, but the method of manufacturing a dehydrogenation catalyst according to an embodiment of the present invention may also be applied to release hydrogen in a material, for example, a liquid organic hydrogen carrier (LOHC).

Meanwhile, in an embodiment of the present invention, a TiO₂ functional oxide coating layer was deposited on 10 g of bead-type γ-Al₂O₃ with atomic layer deposition (ALD) using titanium-isopropoxide (TTIP) and H₂O.

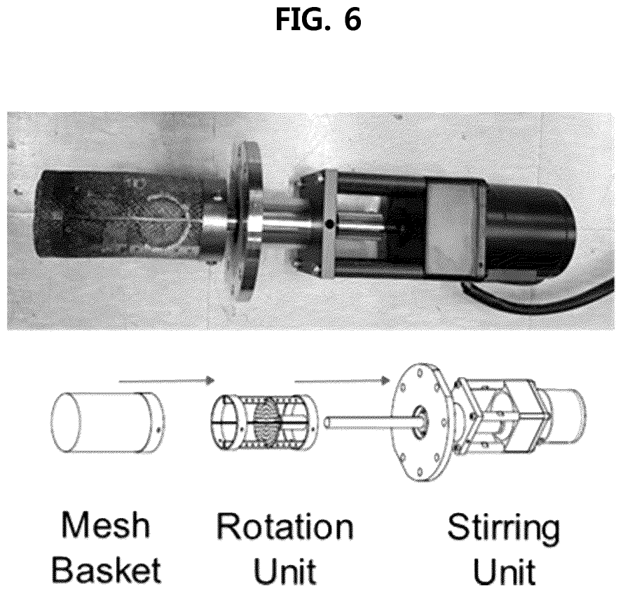

In addition, to increase the uniformity of the TiO₂ layer deposited on the bead-type γ-Al₂O₃, a device equipped with a rotation inner barrel may be applied to be rotated in a reactor of an atomic layer deposition (ALD) device as illustrated in FIG. 6.

In the process of ALD deposition, the temperatures of a main reactor, a TTIP vessel, and a H₂O vessel were set to 175° C., 60° C., and 30° C., respectively, and the process of ALD deposition was carried out in four steps of TTIP (or H₂O) injection (0.3 s)-saturation (1 min)-Ar purging (100 ccm, 15 s)-pumping (5 min).

In addition, by controlling the number of ALD cycles, a thickness of TiO₂, which is a functional oxide layer deposited on the γ-Al₂O₃, was controlled.

In particular, in an embodiment of the present invention, one of the oxides selected from TiO₂, CeO₂, ZrO₂ and Al₂O₃ may be used as the functional oxide.

Specifically, Ru, the metal particles in an embodiment of the present invention, has a binding energy of 141 kcal/mol, which is closest to an optimal value of 134 kcal/mol among single metals, making the Ru the most active metal for ammonia decomposition, thereby improving the catalytic activity by downshifting the d-band center of Ru. This is because the catalytic activity can be enhanced by effectively reducing the adsorption energy and thus activating the desorption behavior.

In addition, the electronic properties of the Ru metal particles may be modulated through interaction with the functional oxide coating layer on which the metal particles are supported.

Specifically, TiO₂, CeO₂, ZrO₂, or Al₂O₃, which is the functional oxide coating layer in an embodiment of the present invention, may increase the catalytic activity by inducing an interaction effect between the aforementioned Ru particles and the functional oxide coating layer.

However, when there is excessive interaction between the metal particles and the functional oxide coating layer, the functional oxide coating layer may encapsulate the metal particles in a high-temperature reductive environment, or the metal particles may bind to the functional oxide coating layer, resulting in a loss of the catalytic activity.

Therefore, in an embodiment of the present invention, the functional oxide coating layer can be applied with the atomic layer deposition to prevent excessive interaction or binding to each other between the metal particles and the functional oxide coating layer.

In addition, through the aforementioned technical principles, active sites on the metal particles may modulate the nitrogen binding energy of the ammonia that is a target for decomposition, thereby increasing a desorption rate of nitrogen molecules generated during a reaction on a surface of the catalyst.

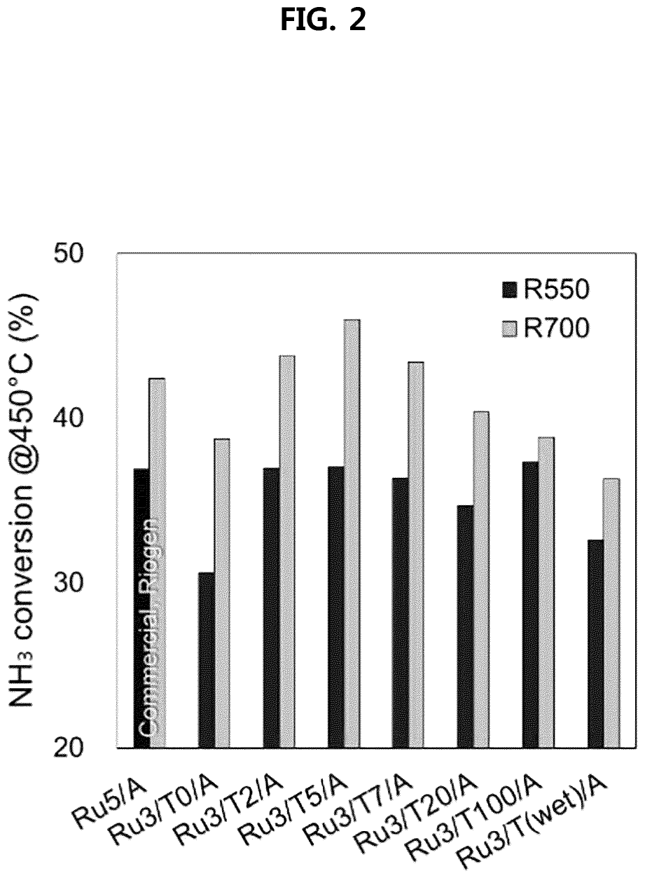

FIG. 2 is a graph illustrating an ammonia conversion rate according to the number of deposition cycles of the functional oxide coating layer for the ammonia decomposition catalysts, specifically, the conversion rate was measured at 450° C. after a reduction process at temperatures of 550° C. and 700° C. for each catalyst, respectively.

As illustrated in FIG. 2, it can be seen that the ammonia conversion rate tends to increase and then decrease as the number of cycles of atomic layer deposition increases, regardless of the reduction temperature.

In addition, when TiO₂, which is the functional oxide coating layer, is deposited in five cycles, it can be seen that the conversion rate is approximately 7% higher than a comparative example in which the functional oxide layer is not introduced.

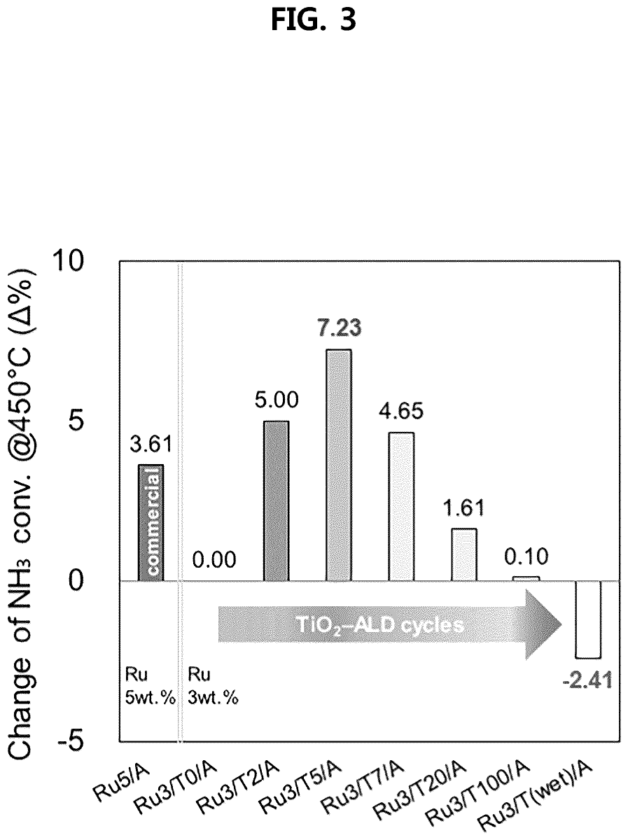

FIG. 3 is a graph illustrating change in ammonia conversion with the number of deposition cycles of the functional oxide coating layer formed according to an embodiment of the present invention.

As illustrated in FIG. 3, the change was calculated based on the decomposition rate measured at 450° C. after the reduction process at a temperature of 700° C. for each catalyst, and as a result, the Ru3/T5/A sample exhibited the highest decomposition rate, which was approximately 7% higher than a decomposition rate of Ru3/A.

In addition, this result exhibited a higher decomposition rate than a commercial catalyst containing 5 wt % Ru, and the catalyst with a TiO₂ layer deposited in 100 cycles exhibited almost the same activity as Ru3/A.

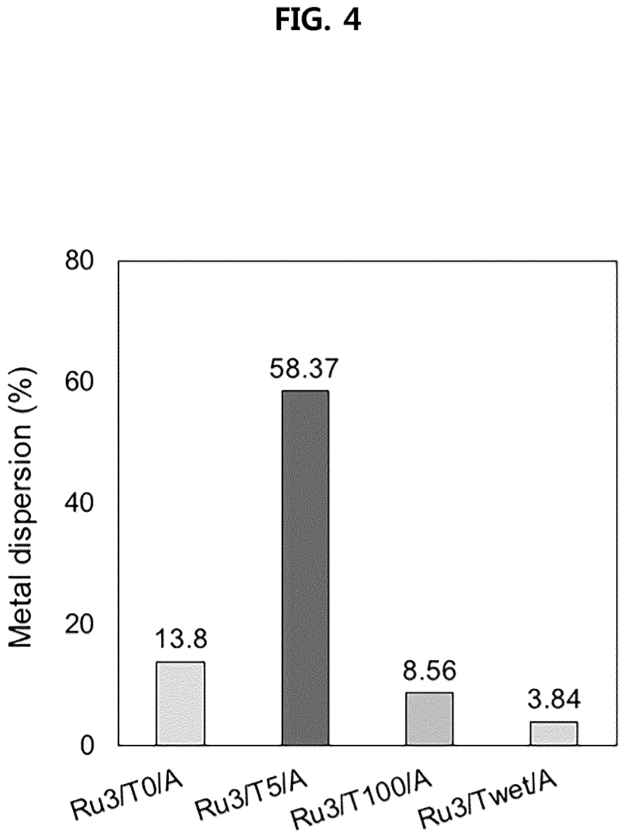

FIG. 4 is a graph illustrating the dispersion of metal particles as a function of the number of deposition cycles of the functional oxide coating layer formed according to an embodiment of the present invention.

As illustrated in FIG. 4, it can be seen that the highest dispersion of metal particles, which is 58.37%, was exhibited when the TiO₂ functional oxide coating layer was deposited in five cycles.

Meanwhile, a Ru3/Twet/A sample with the lowest ammonia decomposition rate exhibited the lowest metal dispersion of 3.64%.

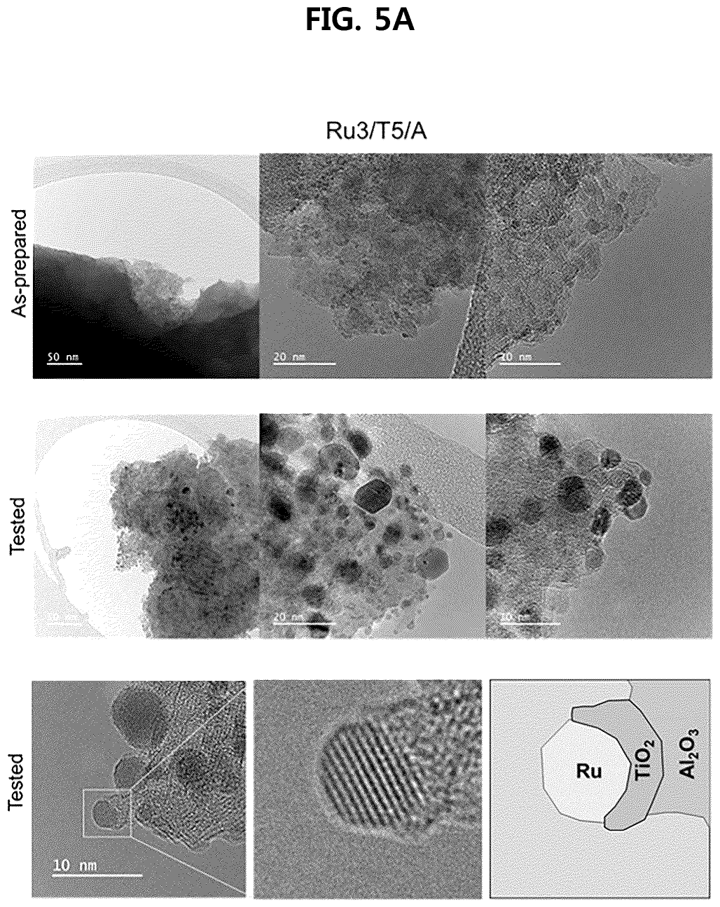

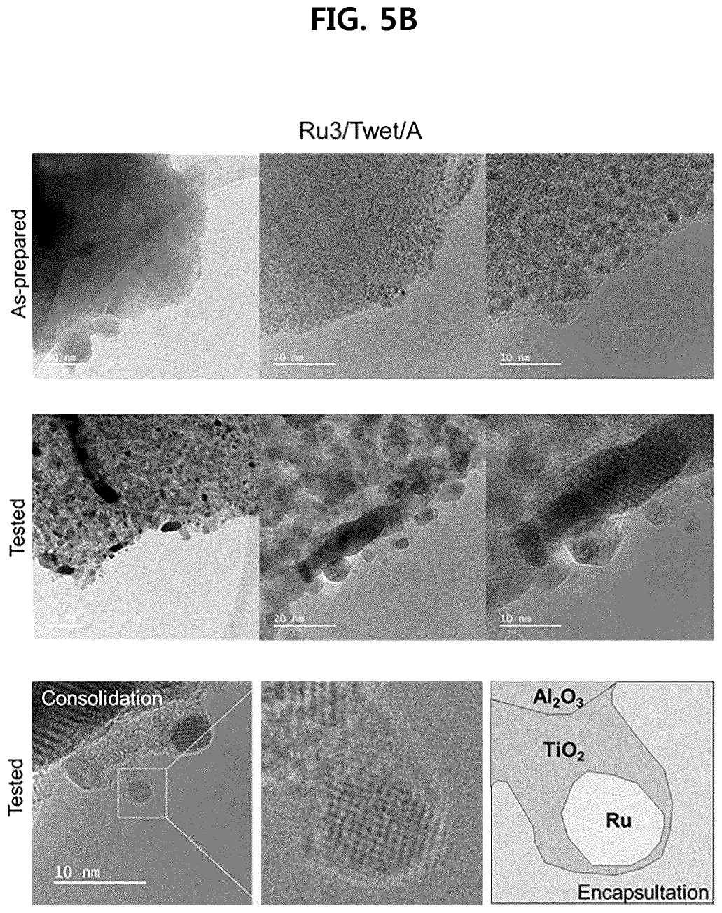

FIG. 5A is STEM images of Ru3/T5/A catalyst manufactured according to an embodiment of the present invention, and FIG. 5B is STEM images of Ru3/Twet/A catalyst t10.

0hat include 3 wt. % of the functional oxide coating layer formed by wet impregnation method as a comparative example.

As illustrated in FIG. 5B, it can be seen that the catalyst with Ru metal particles immersed by a conventional wet impregnation method, the Ru metal particles are surrounded and encapsulated by a TiO₂ layer.

However, as illustrated in FIG. 5A, no encapsulated Ru particles were found in the ammonia decomposition catalyst manufactured according to an embodiment of the present invention.

FIG. 6 is a photograph schematically illustrating a rotating device equipped with an inner barrel in operation for atomic layer deposition as used in an embodiment of the present invention.

As illustrated in FIGS. 1 and 6, the uniformity of the functional oxide coating layer and metal particles being deposited may be further improved by rotating the inner barrel of the ALD deposition device.

A person skilled in the art may understand that the present invention may be carried out in other specific forms with reference to the above-mentioned descriptions without changing the technical spirit or the essential characteristics of the present invention.

Accordingly, it is to be understood that the embodiments described above are illustrative in all respects and are not intended to limit the present invention to the embodiments, and the scope of the present invention is indicated by the patent claims which are hereinafter recited rather than by the foregoing detailed description, and the meaning and scope of the patent claims and all modifications or variations derived from the equivalent concepts should be interpreted to be included within the scope of the present invention.

What is claimed is:

1. A method of manufacturing a dehydrogenation catalyst, the method comprising:
forming a functional oxide coating layer on a surface of a support with a first atomic layer deposition; and
depositing metal particles on the surface of the support on which the functional oxide coating layer is formed, with second atomic layer deposition or wet impregnation.

2. The method of claim 1, wherein the support is porous bead-type Al₂O₃.

3. The method of claim 2, wherein the metal particle is one of the particles selected from Ru, Pt, Ni, Co, and Mo particles.

4. The method of claim 3, wherein the functional oxide is one of the oxides selected from TiO₂, CeO₂, ZrO₂ and Al₂O₃.

5. The method of claim 4, wherein the number of deposition cycles of the atomic layer deposition is performed in five cycles.

6. The method of claim 5, wherein the metal particles are not encapsulated by the functional oxide.

7. The method of claim 6, wherein the dehydrogenation catalyst is subjected to a reduction reaction in a temperature range of 350 to 550° C.

8. The method of claim 7, comprising:
rotating a rotating device equipped with an inner barrel device inside a vacuum reactor during operation of the atomic layer deposition.
